(19) United States
(12) Patent Application Publication
(10) Pub. No.: US 2016/0336968 A1
(43) Pub. Date: Nov. 17, 2016

(54) SYSTEM AND METHOD FOR ENCODING AND DECODING USING A PLURALITY OF CONSTELLATIONS WITHIN A SINGLE FEC BLOCK

(71) Applicant: Comtech EF Data Corp., Tempe, AZ (US)

(72) Inventor: Brian A. Banister, Moscow, ID (US)

(21) Appl. No.: 14/709,283

(22) Filed: May 11, 2015

(51) Int. Cl. H03M 13/11; H04L 1/00

(52) U.S. Cl. CPC H03M 13/1148; H04L 1/0041; H04L 1/0045

(57) ABSTRACT

A method of data transmission and recovery over a communications channel comprising encoding, by an encoder, data using a forward error correction (FEC) code such that a plurality of encoded FEC frames results wherein each encoded FEC frame comprises a FEC codeword mapped to a plurality of symbols from a plurality of constellations, at least two of the constellations being different from one another, transmitting the encoded FEC frames across a communications channel using a transmitter, and decoding the received encoded FEC frames using a decoder at a receiver.

### BACKGROUND

1. Technical Field

Aspects of this document relate generally to the fields of data encoding and decoding.

2. Background Art

An LDPC code is typically described by its variable nodes and its check nodes. Iterative decoding is accomplished by the passing of messages between these variable nodes and the check nodes. Low Density Parity Check (LDPC) codes with non-uniform variable node degree distributions exhibit a property wherein certain variable nodes converge at a rate faster than other variable nodes. Prior art observes this unequal variable node reliability.

In the DVB-S2X standard, the unequal variable node reliability coupled with a non-uniform bit-plane reliability within a constellation results in use of many constellations, some of which are substantially different only in the labeling of the constellation points, meaning that a diagram of the constellation point appears the same, but a mapping of a given bit sequence produces a different resulting sequence of symbols. This phenomenon is seen, for example, in the DVB-S2 standard wherein the labeling is changed for the 3/5 8PSK ModCod. This labeling is changed by changing the bit-interleaver ordering.

In the design of irregular LDPC codes, an assumption is typically made that the input distribution for each variable node is independent and identically distributed (iid). For most constellations other than BPSK and QPSK, this assumption is not true. On BPSK/QPSK, it has been observed that the irregular LDPC codes, those with non-uniform variable node degree distributions, are able to obtain earlier waterfalls than equivalent regular LDPC codes. This has motivated many standards to employ the irregular LDPC codes.

### SUMMARY

Implementations of a method of data transmission and recovery over a communications channel may comprise encoding, by an encoder, data using a forward error correction (FEC) code such that a plurality of encoded FEC frames results wherein each encoded FEC frame comprises a FEC codeword mapped to a plurality of symbols from a plurality of constellations, at least two of the constellations being different from one another, transmitting the encoded FEC frames across a communications channel using a transmitter, and decoding the received encoded FEC frames using a decoder at a receiver.

Particular aspects may comprise one or more of the following features. The FEC may be an irregular low density parity check (LDPC) code, and wherein a choice of a first constellation for a first symbol is selected from a plurality of constellations based upon a variable node degree distributions of variable nodes that map to the first symbol. One or more data variable nodes of the codeword may comprise a variable node degree that is different from a variable node degree of one or more parity variable nodes. A first variable node associated with a FEC codeword may have a higher degree than a second variable node of the FEC codeword and a first symbol containing the first variable node is mapped using a first constellation having a different set of bit-plane capacities than a second constellation by which a second symbol containing the second variable node is mapped. The FEC code may be an LDPC code with uniform variable node degree distribution. The FEC may be a low density parity check (LDPC) code and a choice of a first constellation for a first symbol is selected from a plurality of constellations such that a rate of convergence for one or more variable nodes associated with a first symbol has an increased rate of convergence. The decoding may be constrained to increase a convergence rate of a predetermined portion of the variable nodes of the codeword. The method may further comprise mapping symbols using at least three different constellations. The method may further comprise iteratively decoding a codeword. A necessary signal to nose ratio (SNR) of the communications channel may be reduced by the encoding, mapping, and decoding. The method may further comprise sequentially decoding of one or more symbols such that the decoding of additional symbols has an improved decoding quality.

Implementations of a system of data transmission and recovery over a communications channel may comprise an encoder configured to encode data using a forward error correction (FEC) code such that a plurality of encoded FEC frames results and each encoded FEC frame comprises a FEC codeword that is mapped to a plurality of symbols from a plurality of constellations, at least two of the constellations being different from one another, a transmitter configured to transmit the encoded FEC frames across a communications channel, and a receiver comprising a decoder configured to decode the received encoded FEC frames.

Particular aspects may comprise one or more of the following features. The FEC may be an irregular low density parity check (LDPC) code, and wherein a choice of a first constellation for a first symbol is selected from a plurality of constellations based upon a variable node degree distributions of variable nodes that map to the first symbol. One or more data variable nodes of the codeword may comprise a variable node degree that is different from a variable node degree of one or more parity variable nodes. A first variable node associated with a FEC codeword may have a higher degree than a second variable node of the FEC codeword and a first symbol containing the first variable node is mapped using a first constellation having a different set of bit-plane capacities than a second constellation to which a second symbol containing the second variable node is mapped. The FEC code may be an LDPC code with uniform variable node degree distribution. The FEC may be is a low density parity check (LDPC) code and a choice of a first constellation for a first symbol is selected from a plurality of constellations such that a rate of convergence for one or more variable nodes associated with a first symbol has an increased rate of convergence. The decoder may be constrained to increase a convergence rate of a predetermined portion of the variable nodes of the codeword. The encoder may be further configured to map symbols using at least three different constellations. The decoder may be further configured to iteratively decoding a codeword. A necessary signal to nose ratio (SNR) of the communications channel may be reduced by the encoding, mapping, and decoding. The decoder may be further configured to sequentially decode one or more symbols such that the decoding of additional symbols has an improved decoding quality.

Aspects and applications of the disclosure presented here are described below in the drawings and detailed description. Unless specifically noted, it is intended that the words and phrases in the specification and the claims be given their plain, ordinary, and accustomed meaning to those of ordinary skill in the applicable arts. The inventors are fully aware that they can be their own lexicographers if desired. The inventors expressly elect, as their own lexicographers, to use only the plain and ordinary meaning of terms in the specification and claims unless they clearly state otherwise and then further, expressly set forth the “special” definition of that term and explain how it differs from the plain and ordinary meaning Absent such clear statements of intent to apply a “special” definition, it is the inventors' intent and desire that the simple, plain and ordinary meaning to the terms be applied to the interpretation of the specification and claims.

The inventors are also aware of the normal precepts of English grammar. Thus, if a noun, term, or phrase is intended to be further characterized, specified, or narrowed in some way, then such noun, term, or phrase will expressly include additional adjectives, descriptive terms, or other modifiers in accordance with the normal precepts of English grammar. Absent the use of such adjectives, descriptive terms, or modifiers, it is the intent that such nouns, terms, or phrases be given their plain, and ordinary English meaning to those skilled in the applicable arts as set forth above.

Further, the inventors are fully informed of the standards and application of the special provisions of pre-AIA 35 U.S.C. §112, ¶6 and post-AIA 35 U.S.C. §112(f). Thus, the use of the words “function,” “means” or “step” in the Description, Drawings, or Claims is not intended to somehow indicate a desire to invoke the special provisions of pre-AIA 35 U.S.C. §112, ¶6 and post-AIA 35 U.S.C. §112(f), to define the invention. To the contrary, if the provisions of pre-AIA 35 U.S.C. §112, ¶6 and post-AIA 35 U.S.C. §112(f) are sought to be invoked to define the claimed disclosure, the claims will specifically and expressly state the exact phrases “means for” or “step for, and will also recite the word “function” (i.e., will state “means for performing the function of [insert function]”), without also reciting in such phrases any structure, material or act in support of the function. Thus, even when the claims recite a “means for performing the function of . . . ” or “step for performing the function of . . . ,” if the claims also recite any structure, material or acts in support of that means or step, or that perform the recited function, then it is the clear intention of the inventors not to invoke the provisions of pre-AIA 35 U.S.C. §112, ¶6 and post-AIA 35 U.S.C. §112(f). Moreover, even if the provisions of pre-AIA 35 U.S.C. §112, ¶6 and post-AIA 35 U.S.C. §112(f) are invoked to define the claimed disclosure, it is intended that the disclosure not be limited only to the specific structure, material or acts that are described in the preferred embodiments, but in addition, include any and all structures, materials or acts that perform the claimed function as described in alternative embodiments or forms of the invention, or that are well known present or later-developed, equivalent structures, material or acts for performing the claimed function.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 provides an example of a Tanner graph.

FIG. 2 provides a block diagram of an implementation of a system for data transmission and recovery over a communications channel.

FIG. 3 provides an example of an interleaver structure in accordance with an implementation of the disclosed system and methods.

### DESCRIPTION

This disclosure, its aspects and implementations, are not limited to the specific components, frequency examples, or methods disclosed herein. Many additional components and assembly procedures known in the art consistent with data encoding and decoding methodologies are in use with particular implementations from this disclosure. Accordingly, for example, although particular implementations are disclosed, such implementations and implementing components may comprise any components, models, versions, quantities, and/or the like as is known in the art for such systems and implementing components, consistent with the intended operation.

The systems and methods described in this disclosure seek to further improve Forward Error Correction (FEC) performance by noting and utilizing the performance dependence between the variable node degree distribution and the constellation employed. In particular, it is noted that the degree distributions associated with the bits of an n-tuple mapped to a given symbol are not static across the collection of symbols in a FEC block. As discussed in a later example, some symbols may be mappings of n-tuples containing multiple bits associated with high degree variable nodes while n-tuples for other symbols may have fewer bits associated with high degree variable nodes. As such, changing the constellation when the variable degree node distributions of the bits in the n-tuple change in accordance with the disclosed systems and methods serves to improve the FEC performance.

This disclosure is not intended to be limited to binary codes as the systems and methods disclosed herein are applicable to non-binary codes as well. As such, the term “bits” as used in this disclosure is used rather than “symbols” as is commonly used when referring to elements of non-binary codes to avoid confusion between what is meant by mapping of “bits” in an n-tuple to “symbols” of a constellation.

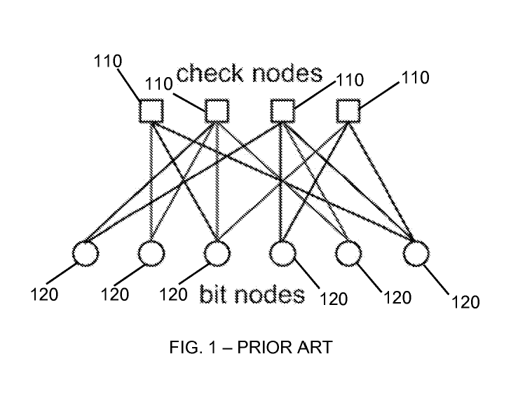

For reference, FIG. 1 provides an example of a Tanner graph 100. For linear block codes, the check nodes 110 denote rows of a parity-check matrix and the bit nodes 120 represent columns of the parity check matrix. The connections between the check nodes and bit nodes exist if a nonzero entry is present at the corresponding column and row intersection of the parity-check matrix.

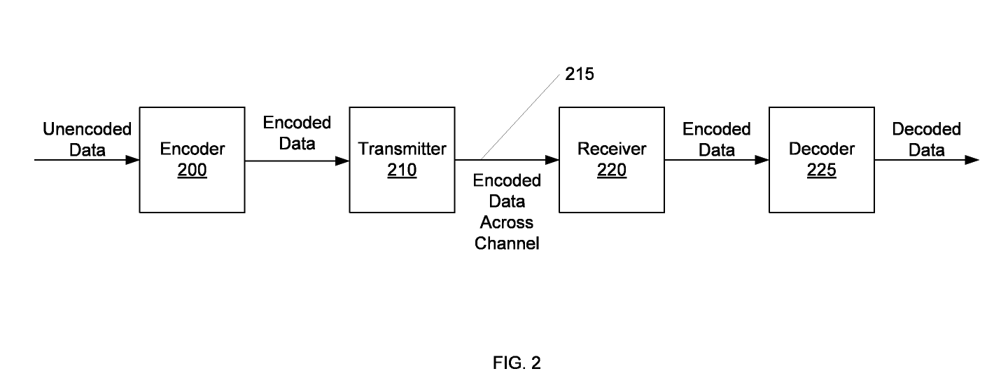

For implementations of a system using a FEC having a variable node degree distribution, the encoder 200, as shown in FIG. 2 may encode a plurality of FEC frames so that each FEC frame comprises a FEC codeword (FEC block) that is partitioned into a plurality of n-tuples that are mapped to a plurality of symbols using a plurality of constellations and at least two of these constellations are different from one another. A transmitter 210 then transmits the FEC frames across a communications channel 215 to a receiver 220 where a decoder 225 decodes the FEC frames. While the disclosed systems and methods are not limited to the use of a low density parity check (LDPC) FEC code, implementations of the systems and methods described herein are certainly applicable when using LDPC codes. For example, in some irregular LDPC implementations, a choice of a first constellation for a first symbol may be selected from a plurality of constellations based on a variable degree distribution of variable nodes that map to the first symbol. Any of the data variable nodes of the FEC codeword may comprise a variable node degree that is different from a variable node degree of a parity variable node.

When an irregular LDPC code is used, it is possible that a first variable node associated with a FEC codeword has a higher degree than a second variable node of the FEC codeword. In accordance with an implementation of the disclosed system and method, a first n-tuple that contains the first variable node may be mapped to a first symbol using a first constellation that has a different set of bit-plane capacities than a second constellation by which a second n-tuple containing a second variable node is mapped to a second symbol.

The systems and methods of this disclosure are also intended to be applicable to a FEC code with uniform variable node degree distribution. In this instance, a plurality of constellations within a FEC frame may be used to produce an effect similar to having a non-uniform variable node distribution. This may be used to aid in the early stages of an iterative decoder by allowing certain variable nodes to gain “traction” earlier by converging more quickly among those variable nodes. In some implementations, for example, when an LDPC code is used, a choice of a first constellation for a first symbol may be selected from a plurality of constellations so that a rate of convergence for one or more variable nodes associated with the first symbol has an increased rate of convergence.

Another class of error correction codes called “spatially coupled LDPC codes” (SC-LDPC) rely upon a staggered decoding process and constrained startup conditions to produce this same effect wherein a portion of variable nodes are allowed to gain “traction” earlier. These early traction variable nodes are then able to better assist in the convergence of other variable nodes which will in turn assist yet others. In some such implementations, the decoding may be constrained to increase a convergence rate of a predetermined portion of the variable nodes of the FEC codeword. With or without the use of the SC-LDPC construct, implementations of the disclosed systems and methods may control the early traction process by employing a plurality of constellations with a single FEC frame.

It should be noted that this disclosure is directed toward implementations of systems and methods that use multiple constellations within a “FEC frame”, not merely among the entire “frame” itself. One of ordinary skill in the art would recognize that it is common to have a preamble marker coded with BPSK or QPSK followed by the payload (the FEC codeword or FEC block) that is mapped to symbols of the “FEC frame” using a different constellation such as 8-PSK or 32-APSK. The use of “pilot” symbols placed periodically within a frame is also common, and introduces a subset of symbols within the frame which may not use the same constellation as the FEC frame. The systems and methods of this disclosure are intended to distinguish themselves from the prior art by specifically using multiple constellations within a FEC frame itself, which has not previously been accomplished by others in this art. The use of the term “FEC frame” in this disclosure is intended to refer to the symbols associated with the bits of a FEC codeword/block in an effort to further distinguish this from the physical layer framing structure herein referred to as a “frame”. For purposes of this disclosure, reference to “bits of a symbol” is intended to be construed as those bits (i.e. variable nodes) partitioned into an n-tuple and then mapped to a symbol by use of a constellation.

Regardless of whether an irregular or uniform variable node degree distribution is employed, the implementations of this disclosure provide better overall performance of the system because the symbol mappings used are selected in a manner that improves the ability of the FEC to correct errors. While the purpose of FEC is to correct errors that have occurred, the ability of a given code to correct the errors depends upon the construction of the code, the rate of the code, and the amount of errors. The code rate is defined as the ratio of the quantity of input data over the quantity of output data produced by the FEC encoder. For additive white Gaussian noise (AWGN) and similar channels, the “frequency” or type of errors which occur depend upon the ratio between signal power and noise power, typically described as signal to noise ratio (SNR). A channel across which the encoded FEC block is transmitted has a specific channel capacity that is related to the SNR for the AWGN channel. If the capacity of the channel is lower than the ability of the FEC code to deal with it, then the FEC block will fail to decode. If the SNR is increased, there will be a smaller percentage of errors that the FEC cannot correct. The waterfall region refers to the SNR range at which there is a rapid transition from a high error rate to a low error rate as the SNR is increased. In comparing two systems, whichever system reaches this tipping point or “waterfall” at a lower SNR, all else being equal, is described as having better performance.

The following non-limiting example is used for illustrative purposes only and is not intended to limit the scope of this disclosure in any manner. Take for example, a rate 1/2 code, comprised of data variable nodes having a degree of four and parity variable nodes having a degree of two as applied to a 3-bit/symbol constellation (such as, for example, 8-PSK). In this example, the code is assumed to by systematic, with all data being placed inside the FEC block prior to all parity. A three-column bit interleaver scheme like that of DVB-S2 may be employed.

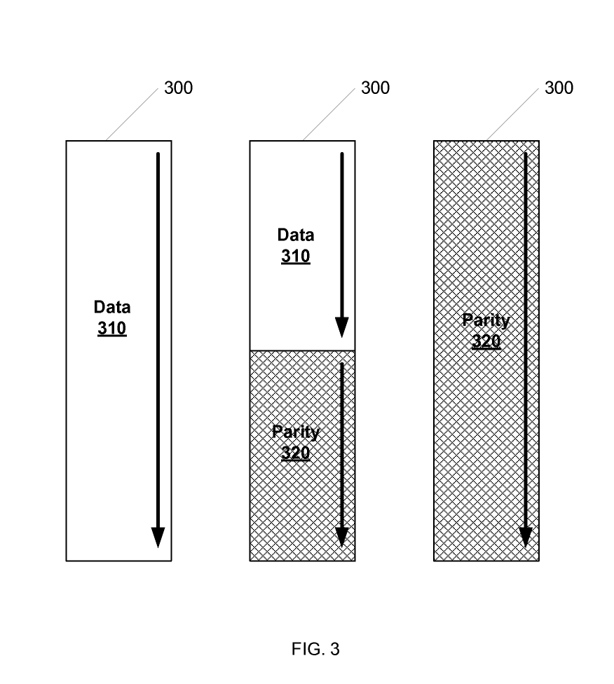

FIG. 3 provides an example of this interleaver structure. The FEC codeword is placed into the interleaver, filling each column in turn from left to right, with each column 300 being filled from top to bottom. The content is read out of the interleaver on a row-by-row basis, starting with the top row. The 3-tuple in each row is mapped onto a single “3-bit” symbol. If there are N symbols, the first N/2 symbols are comprised of two data bits from among the data payload 310 and one parity bit from among the parity portion 320. The second N/2 symbols are comprised of one data bit from among the data payload 310 and two parity bits from among the parity portion 320. Since the data variable nodes and the parity variable nodes have different degrees, in accordance with an implementation of the disclosed system and methods, a first constellation, A, is used for symbols 1 . . . N/2 and a second constellation, B, for symbols N/2+1 . . . N.

Even in this example, there may be additional gains associated with using more than two constellations. For example, it may be beneficial to use a first constellation, A, for 1 . . . N/4, a second constellation, B, for N/4+1 . . . N/2, and a third constellation, C, for N/2+1 . . . N. Such an approach could be used, for example, to provide earlier traction for a portion of the data variable nodes (for example, through the use of constellation A), and then providing more balanced distributions for the remaining data variable nodes.

In places where the description above refers to particular implementations systems and methods for encoding and decoding data, it should be readily apparent that a number of modifications may be made without departing from the spirit thereof and that these implementations may be applied to other encoding and decoding systems and methods.

1. A method of data transmission and recovery over a communications channel comprising:
encoding, by an encoder, data using a forward error correction (FEC) code such that a plurality of encoded FEC frames results wherein each encoded FEC frame comprises a FEC codeword mapped to a plurality of symbols from a plurality of constellations, at least two of the constellations being different from one another;
transmitting the encoded FEC frames across a communications channel using a transmitter; and
decoding the received encoded FEC frames using a decoder at a receiver.

2. The method of claim 1, wherein the FEC is an irregular low density parity check (LDPC) code, and wherein a choice of a first constellation for a first symbol is selected from a plurality of constellations based upon a variable node degree distributions of variable nodes that map to the first symbol.

3. The method of claim 2, wherein one or more data variable nodes of the codeword comprise a variable node degree that is different from a variable node degree of one or more parity variable nodes.

4. The method of claim 2, wherein a first variable node associated with a FEC codeword has a higher degree than a second variable node of the FEC codeword and a first symbol containing the first variable node is mapped using a first constellation having a different set of bit-plane capacities than a second constellation by which a second symbol containing the second variable node is mapped.

5. The method of claim 1, wherein the FEC code is an LDPC code with uniform variable node degree distribution.

6. The method of claim 1, wherein the FEC is a low density parity check (LDPC) code and a choice of a first constellation for a first symbol is selected from a plurality of constellations such that a rate of convergence for one or more variable nodes associated with a first symbol has an increased rate of convergence.

7. The method of claim 6, wherein the decoding is constrained to increase a convergence rate of a predetermined portion of the variable nodes of the codeword.

8. The method of claim 6, further comprising mapping symbols using at least three different constellations.

9. The method of claim 1, further comprising iteratively decoding a codeword.

10. The method of claim 1, wherein a necessary signal to nose ratio (SNR) of the communications channel is reduced by the encoding, mapping, and decoding.

11. The method of claim 1, further comprising sequentially decoding of one or more symbols such that the decoding of additional symbols has an improved decoding quality.

12. A system of data transmission and recovery over a communications channel comprising:
an encoder configured to encode data using a forward error correction (FEC) code such that a plurality of encoded FEC frames results and each encoded FEC frame comprises a FEC codeword that is mapped to a plurality of symbols from a plurality of constellations, at least two of the constellations being different from one another;
a transmitter configured to transmit the encoded FEC frames across a communications channel; and
a receiver comprising a decoder configured to decode the received encoded FEC frames.

13. The system of claim 12, wherein the FEC is an irregular low density parity check (LDPC) code, and wherein a choice of a first constellation for a first symbol is selected from a plurality of constellations based upon a variable node degree distributions of variable nodes that map to the first symbol.

14. The system of claim 13, wherein one or more data variable nodes of the codeword comprise a variable node degree that is different from a variable node degree of one or more parity variable nodes.

15. The system of claim 13, wherein a first variable node associated with a FEC codeword has a higher degree than a second variable node of the FEC codeword and a first symbol containing the first variable node is mapped using a first constellation having a different set of bit-plane capacities than a second constellation to which a second symbol containing the second variable node is mapped.

16. The system of claim 12, wherein the FEC code is an LDPC code with uniform variable node degree distribution.

17. The system of claim 12, wherein the FEC is a low density parity check (LDPC) code and a choice of a first constellation for a first symbol is selected from a plurality of constellations such that a rate of convergence for one or more variable nodes associated with a first symbol has an increased rate of convergence.

18. The system of claim 17, wherein the decoder is constrained to increase a convergence rate of a predetermined portion of the variable nodes of the codeword.

19. The system of claim 17, wherein the encoder is further configured to map symbols using at least three different constellations.

20. The system of claim 12, wherein the decoder is further configured to iteratively decoding a codeword.

21. The system of claim 12, wherein a necessary signal to nose ratio (SNR) of the communications channel is reduced by the encoding, mapping, and decoding.

22. The system of claim 12, wherein the decoder is further configured to sequentially decode one or more symbols such that the decoding of additional symbols has an improved decoding quality.
